(19) United States
(12) Patent Application Publication
(10) Pub. No.: US 2025/0212621 A1
(43) Pub. Date: Jun. 26, 2025

(54) DISPLAY PANEL, DISPLAY APPARATUS, AND METHOD FOR MANUFACTURING DISPLAY PANEL

(71) Applicant: Hefei Visionox Technology Co., Ltd., Hefei (CN)

(72) Inventors: Siming GAO, Hefei (CN); Junwei LIU, Hefei (CN); Zhimin YAN, Hefei (CN)

(73) Assignee: Hefei Visionox Technology Co., Ltd., Hefei (CN)

(21) Appl. No.: 19/074,479

(22) Filed: Mar. 10, 2025

Related U.S. Application Data
(63) Continuation of application No. PCT/CN2023/135144, filed on Nov. 29, 2023.

(30) Foreign Application Priority Data
Jun. 13, 2023 (CN) 202310707276.2

(51) Int. Cl. H10K 59/122; H10K 59/12; H10K 59/80

(52) U.S. Cl. CPC H10K 59/122; H10K 59/1201; H10K 59/80521; H10K 59/873

(57) ABSTRACT

The present application provides a display panel, a display apparatus, and a method for manufacturing a display panel. The display panel includes: a base plate; a pixel defining layer including a pixel defining portion and a plurality of pixel openings enclosed and formed by the pixel defining portion; a first mask portion including one or more first openings arranged through the first mask portion along a thickness direction of the display panel; and a first electrode located at a side of the pixel defining layer away from the base plate and a side of the first mask portion away from the base plate, the first electrode including at least one second opening arranged through the first electrode along the thickness direction, and an orthographic projection of the second opening on the base plate at least partially overlapping an orthographic projection of the first opening on the base plate.

### CROSS REFERENCE TO RELATED APPLICATION

The present application is a continuation application of International Application No. PCT/CN2023/135144, filed on Nov. 29, 2023, which claims priority to Chinese Patent Application No. 202310707276.2 filed on Jun. 13, 2023, both of which are incorporated herein by reference in their entireties.

### FIELD

The present application relates to the field of display technology, and particularly to a display panel, a display apparatus, and a method for manufacturing a display panel.

### BACKGROUND

Planar display apparatus based on Organic Light Emitting Diode (OLED) and Light Emitting Diode (LED), etc., are widely used in cell phones, TVs, notebook computers, desktop computers, and other consumer electronic products due to their high image quality, power saving, thin body, wide range of applications and other advantages, and have become the mainstream of the display apparatus.

However, the encapsulation reliability of the existing OLED display products, after cathode patterning, needs to be improved.

### SUMMARY

Embodiments of the present application provide a display panel, a display apparatus, and a method for manufacturing a display panel, which can improve the encapsulation reliability.

Some embodiments of a first aspect of the present application provide a display panel, including: a base plate; a pixel defining layer arranged at one side of the base plate, the pixel defining layer including a pixel defining portion and a plurality of pixel openings enclosed and formed by the pixel defining portion; a first mask portion located a side of the pixel defining portion away from the base plate, the first mask portion including one or more first openings arranged through the first mask portion along a thickness direction of the display panel; and a first electrode located at a side of the pixel defining layer away from the base plate and a side of the first mask portion away from the base plate, the first electrode including at least one second opening arranged through the first electrode along the thickness direction, and an orthographic projection of the second opening on the base plate at least partially overlapping an orthographic projection of the first opening on the base plate.

Some embodiments of a second aspect of the present application provide a display apparatus including the display panel according to any one of the embodiments of the first aspect.

Some embodiments of a third aspect of the present application provide a method of manufacturing a display panel, including: preparing a pixel defining layer at one side of a base plate, the pixel defining layer including a pixel defining portion and a plurality of pixel openings enclosed and formed by the pixel defining portion; preparing a first mask portion at a side of the pixel defining portion away from the base plate, the first mask portion including one or more first openings arranged along a thickness direction of the display panel; preparing an organic material layer at a side of the first mask portion away from the base plate; and arranging a first electrode material layer at a side of the organic material layer away from the base plate, and patterning the first electrode material layer to form a first electrode including at least one second opening, and an orthographic projection of the second opening on the base plate at least partially overlapping an orthographic projection of the first opening on the base plate.

In the display panel according to the embodiments of the present application, the display panel includes the base plate, and the pixel defining layer, the first mask portion, and the first electrode arranged on the base plate. The pixel defining layer includes the pixel defining portion and the pixel openings, and the pixel openings are configured to arrange light-emitting units to achieve light emitting and display of the display panel. The first electrode includes the second opening arranged through the first electrode along the thickness direction, which can reduce the distribution area of the first electrode and increase the light transmittance of the display panel. The first mask portion includes the first opening arranged through the first mask portion along the thickness direction, and a laser or the like can pass through the first opening. The orthographic projection of the second opening on the base plate at least partially overlaps the orthographic projection of the first opening on the base plate, and the second opening can be formed in the first electrode by the incident laser from the first opening, and since the first mask portion is located at the side of the pixel defining portion away from the base plate, the edge of the first mask portion towards the first opening can form a thickness difference, and thus the connection of the first electrode at the first opening of the first mask portion is weak. When the first electrode is laser patterned using the first mask portion as a mask, the first electrode is easily to be disconnected at the edge of the first opening, which can reduce the problem that the edge of the first electrode towards the second opening is likely to upwarp, thereby avoiding the uparping first electrode from affecting the yield of the subsequent encapsulation layer, to increase the encapsulation reliability of the display panel.

### BRIEF DESCRIPTION OF THE DRAWINGS

FIG. 1 shows a schematic top structural diagram of a display panel according to an embodiment of the present application;

FIG. 2 shows a cross-sectional view at A-A in FIG. 1;

FIG. 3 shows a cross-sectional view at B-B in FIG. 1;

FIG. 4 shows a cross-sectional view at B-B in FIG. 1 in another example;

FIG. 5 shows a cross-sectional view at B-B in FIG. 1 in yet another example;

FIG. 6 shows a partially enlarged structural diagram at I in FIG. 2 in one example;

FIG. 7 shows a partially enlarged structural diagram at I in FIG. 2 in another example;

FIG. 8 shows a partially enlarged structural diagram at I in FIG. 2 in yet another example;

FIG. 9 shows a schematic flow chart of a method for manufacturing a display panel according to an embodiment of the present application;

FIG. 10 shows a schematic flow chart of a method for manufacturing a display panel according to another embodiment of the present application.

### DETAILED DESCRIPTION

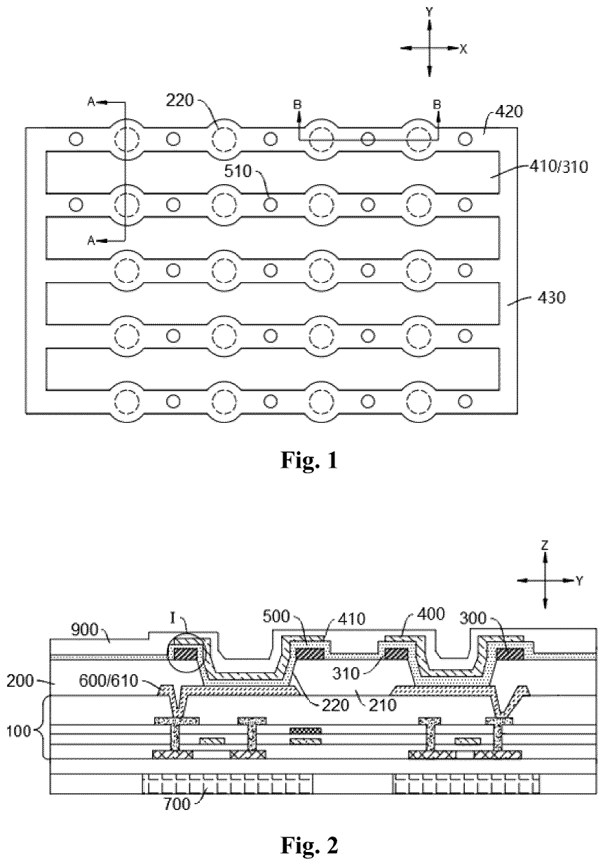

As shown in FIGS. 1 to 3, the embodiments of the first aspect of the present application provide a display panel including a base plate 100, a pixel defining layer 200, a first mask portion 300, and a first electrode 400. The pixel defining layer 200 is arranged at one side of the base plate 100, the pixel defining layer 200 includes a pixel defining portion 210 and a plurality of pixel openings 220 enclosed and formed by the pixel defining portion 210; the first mask portion 300 is located a side of the pixel defining portion 210 away from the base plate 100, the first mask portion 300 includes one or more first openings 310 arranged through the first mask portion 300 along a thickness direction Z of the display panel; and the first electrode 400 is located at a side of the pixel defining layer 200 away from the base plate 100 and a side of the first mask portion 300 away from the base plate 100, the first electrode 400 includes at least one second opening 410 arranged through the first electrode 400 along the thickness direction Z, and an orthographic projection of the second opening 410 on the base plate 100 at least partially overlaps an orthographic projection of the first opening 310 on the base plate 100.

In the display panel according to the embodiments of the present application, the display panel includes the base plate 100, and the pixel defining layer 200, the first mask portion 300, and the first electrode 400 arranged on the base plate 100. The pixel defining layer 200 includes the pixel defining portion 210 and the pixel openings 200, and the pixel openings 220 are configured to arrange light-emitting units to achieve light emitting and display of the display panel. The first electrode 400 includes the second opening 410 arranged through the first electrode 410 along the thickness direction Z, which can reduce the distribution area of the first electrode 400 and increase the light transmittance of the display panel. The first mask portion 300 includes the first opening 310 arranged through the first mask portion 300 along the thickness direction Z, and a laser or the like can pass through the first opening 310. The orthographic projection of the second opening 410 on the base plate 100 at least partially overlaps the orthographic projection of the first opening 310 on the base plate 100, and the second opening 410 can be formed in the first electrode 400 by the incident laser from the first opening 310, and since the first mask portion 300 is located at the side of the pixel defining portion 210 away from the base plate 100, the edge of the first mask portion 300 towards the first opening 310 can form a thickness difference, and thus the connection of the first electrode 400 at the first opening 310 of the first mask portion 300 is weak. When the first electrode 400 is laser patterned using the first mask portion 300 as a mask, the first electrode 400 is easily to be disconnected at the edge of the first opening 310, which can reduce the problem that the edge of the first electrode 400 towards the second opening 410 is likely to upwarp, thereby avoiding the uparping first electrode 400 from affecting the yield of the subsequent encapsulation layer, to increase the encapsulation reliability of the display panel.

The base plate 100 may include a substrate and an array base plate arranged at one side of the substrate, and the array base plate includes a first electrically conductive layer, a second electrically conductive layer, and a third electrically conductive layer that are stacked. An insulating layer is arranged between any adjacent electrically conductive layers. Exemplarily, a drive circuit arranged in the array base plate includes a transistor and a storage capacitor. The transistor includes a semiconductor, a gate, a source, and a drain. The storage capacitor includes a first electrode plate and a second electrode plate. As an example, the gate and the first electrode plate may be located in the first electrically conductive layer, the second electrode plate may be located in the second electrically conductive layer, and the source and the drain may be located in the third electrically conductive layer.

In one embodiment, the orthographic projection of the second opening 410 on the base plate 100 completely overlaps the orthographic projection of the first opening 310 on the base plate 100, and as shown in FIG. 1, the location of the second opening 410 and the location of first opening 310 are the same and shown by the same opening structure. In other embodiments, the orthographic projection of the second opening 410 on the base plate 100 may not completely overlap the orthographic projection of the first opening 310 on the base plate 100, and in a top view of the display panel, a portion of the second opening 410 and a portion the first opening 310 are spaced apart and not formed as the same opening structure.

In one embodiment, the display panel further includes an encapsulation layer arranged at a side of the first electrode 400 away from the base plate 100. In the embodiments of the present application, the first mask portion 300 is arranged at the side of the pixel defining portion 210 away from the base plate 100, and the distance between the first mask portion 300 and the first electrode 400 is less, and when the first electrode 400 is patterned using the first mask portion 300 to form the second opening 410, the edge of the first electrode 400 towards the second opening 410 is less likely to upwarp, which can reduce the effect of upwarping of the first electrode 400 on the encapsulation layer, thereby improving the encapsulation performance of the encapsulation layer.

In one embodiment, the display panel further includes a second electrode layer 600 located at a side of the pixel defining layer 200 towards the base plate 100, the second electrode layer 600 includes a plurality of second electrodes 610 distributed at intervals, the second electrode 610 is arranged corresponding to the pixel opening 220, and the second electrode 610 and the first electrode 400 interact to drive the light-emitting unit within the pixel opening 220 to emit light. One of the first electrode 400 and the second electrode 610 is an anode, and the other one is a cathode. In the embodiments of the present application, for example, the first electrode 400 is the cathode, and the second electrode 610 is the anode.

In some embodiments, referring to FIGS. 1 and 4 together, the display panel further includes an organic material layer 500 located at the side of the first mask portion 300 away from the base plate 100, the organic material layer 500 includes one or more through holes 510 arranged through the organic material layer 500 along the thickness direction Z, and the first electrode 400 is electrically connected with the first mask portion 300 via the through holes 510.

In these embodiments, the first electrode 400 is electrically connected with the first mask portion 300 via the through holes 510, which can reduce the impedance of the first electrode 400 and improve the display effect of the display panel.

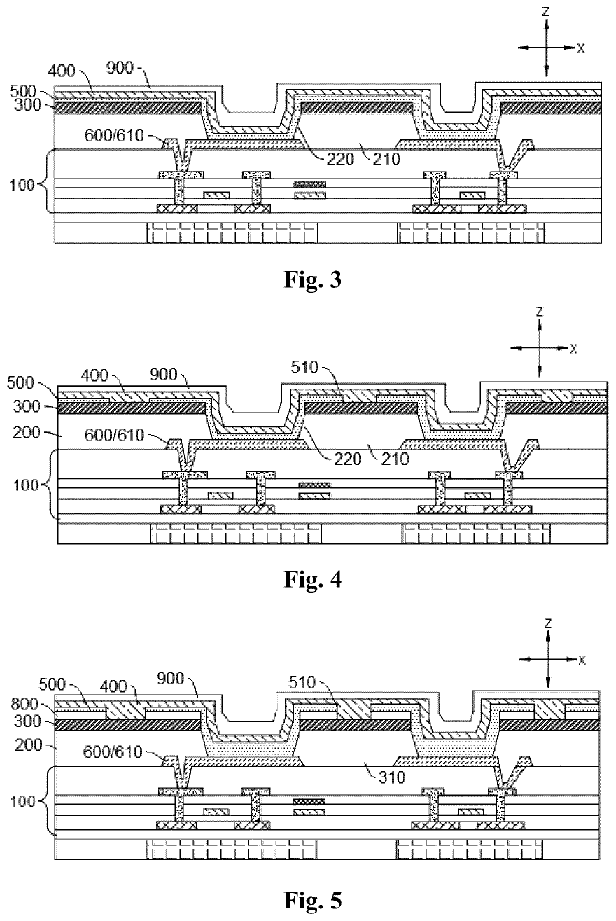

In other embodiments, as shown in FIG. 3, the organic material layer 500 may not be provided with through hole.

In one embodiment, the organic material layer 500 includes a common layer. For example, the organic material layer 500 includes at least one of a hole injection layer, a hole transport layer, an electron blocking layer, a hole blocking layer, an electron transport layer, or an electron injection layer.

In one embodiment, as shown in FIGS. 1 and 4, an orthographic projection of the through hole 510 on the base plate 100 is located within an orthographic projection of the pixel defining portion 210 on the base plate 100. Therefore, the through hole 510 is spaced apart from the pixel opening 220, to avoid the through hole 510 from affecting the light emitting effect of the light-emitting unit.

In one embodiment, the orthographic projection of the through hole 510 on the base plate 100 is located within an orthographic projection of the first mask portion 300 on the base plate 100. It is ensured that the area of the first mask portion 300 exposed by the through hole 510 is large enough and the first electrode 400 is electrically connected with the first mask portion 300 via the through hole 510.

In one embodiment, the orthographic projection of the through hole 510 on the base plate 100 is spaced apart from the orthographic projection of the first opening 310 on the base plate 100. The overlapping between the through hole 510 and the first opening 310 is avoided, which otherwise causes a small area of the first mask portion 300 to be exposed by the through hole 510 and affects the electrical connection between the first electrode 400 and the first mask portion 300.

In one embodiment, a plurality of the through holes 510 are distributed at intervals. By arranging the plurality of through holes 510, the connection area between the first electrode 400 and the first mask portion 300 can be increased, thereby further reducing the impedance of the first electrode 400.

In one embodiment, at least one through hole 510 is arranged between two pixel openings 220 adjacent along a first direction X, the first opening 310 is located at one side of the through hole 510 in a second direction Y, and the first direction Y intersects the second direction X. By arranging the through hole 510 between the pixel openings 220 adjacent along the first direction X, the number of the through holes 510 can be increased to further reduce the impedance of the first electrode 400, and by arranging the first opening 310 at one side of the through hole 510 in the second direction Y, the communication between the first opening 310 and the through hole 510 can be avoided, which otherwise affects the electrical connection between the first electrode 400 and the first mask portion 300.

In one embodiment, as shown in FIG. 5, an insulating layer 800 is arranged between the first mask portion 300 and the organic material layer 500, to reduce the effect of the electrical connection between the organic material layer 500 and the first mask portion 300 on the light emitting effect of the display panel. In one embodiment, if the organic material layer 500 is provided with the through hole 510 for the electrical connection between the first electrode 400 and the first mask portion 300, the insulating layer 800 is also provided with a through hole for the electrical connection between the first electrode 400 and the first mask portion 300.

In some embodiments, as shown in FIG. 1, the first opening 310 extends along the first direction X, a plurality of the first openings 310 are distributed at intervals along the second direction Y, and the first direction X intersects the second direction Y.

In these embodiments, the first opening 310 extends along the first direction X to increase the distribution area of the individual first opening 310, and by arranging the plurality of first openings 310 to be distributed at intervals along the second direction Y, the first electrode 400 can be interconnected between the adjacent first openings 310 and the total area of the first openings 310 can be increased, to increase the light transmittance of the first electrode 400.

In one embodiment, the first opening 310 is extended and formed along the first direction X, i.e., the extension size of the first opening 310 in the first direction X is greater than the extension size of the first opening 310 in the second direction Y In one embodiment, the first opening 310 is located between two rows of the pixel openings 220 adjacent along the second direction Y, to avoid the first opening 310 from affecting the light emitting of the light-emitting unit.

In one embodiment, the display panel may include a display area, the display area may include a first display area and a second display area surrounding at least a portion of the first display area, the light transmittance of the first display area is greater than the light transmittance of the second display area, and the first display area may be configured to arrange a photosensitive component such as an under-screen camera.

In one embodiment, as shown in FIG. 1, the first opening 310 is located in the first display area, and the first opening 310 may extend within the first display area along the first direction X to a boundary between the first display area and the second display area. The first opening 310 is not located in the second display area, and the first electrodes 400 may be interconnected within the second display area.

In one embodiment, the display panel includes a display area and a non-display area surrounding at least a portion of the display area, and the first opening 310 extends in the display area along the first direction X to the display area and the non-display area. The extension of the first opening 310 is great, which can increase the light transmittance of the display area.

In one embodiment, the size of the second opening 410 and the size of the first opening 310 are adapted, for example, the orthographic projection of the second opening 410 on the base plate 100 completely overlaps the orthographic projection of the first opening 310 on the base plate 100. Thus, as shown in FIG. 1, the distribution pattern of the second openings 410 and the distribution pattern of the first openings 310 may be the same.

In one embodiment, if the size of the second opening 410 and the size of the first opening 310 are different, the distribution pattern of the second openings 410 and the distribution pattern of the first openings 310 may also be different. For example, the spacing between two second openings 410 adjacent along the second direction Y and the distance between two first openings 310 adjacent along the second direction Y may be different.

In some embodiments, the first electrode 400 includes a first sub-portion 420 and a second sub-portion 430 connected with each other, the first sub-portion 420 extends along the first direction X, the first electrode 400 includes a plurality of the first sub-portions 420, the plurality of first sub-portions 420 are arranged at intervals along the second direction Y, and the second sub-portion 430 is located at at least one side of the first sub-portion 420 in the first direction X and configured to connect at least two adjacent ones of the first sub-portions 420.

In these embodiments, the first electrode 400 includes the first sub-portion 420 and the second sub-portion 430, and the first sub-portion 420 and the second sub-portion 430 enclose and form the second opening 410 described above. The first sub-portion 420 extends along the first direction X and is located between two adjacent second openings 410, and the second sub-portion 430 is located at one end of the first sub-portion 420 in the first direction X and at one end of the second opening 410 in the first direction X to connect the adjacent first sub-portions 420, and the first sub-portion 420 and the second sub-portion 430 are interconnected to form a whole planar electrode.

In some embodiments, the first mask portion 300 has a thickness greater than or equal to 1000 angstroms. The thickness of the first mask portion 300 is great, and a height difference can be formed at the edge of the second opening 410 of the first mask portion 300, and thus when the first electrode 400 is prepared after the first mask portion 300, the first electrode 400 is weakly connected and easily to be disconnected at the edge of the second opening 410.

In one embodiment, the material of the first mask portion 300 includes an electrically conductive material. Therefore, the impedance of the first electrode 400 can be reduced when the first mask portion 300 and the first electrode 400 are connected.

In one embodiment, the material of the first mask portion 300 includes one or more of silver, indium tin oxide, molybdenum, titanium, or aluminum, and the first mask portion 300 has both good conductivity and stable performance, deformation is less likely to occur when the first electrode 400 is patterned using the first mask portion 300, and the like.

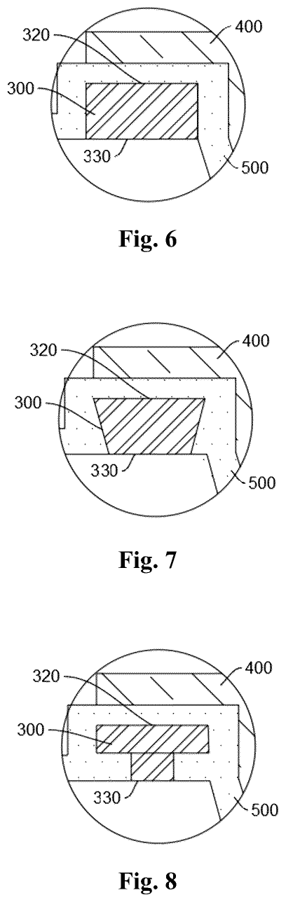

In some embodiments, as shown in FIGS. 6 to 8, the first mask portion 300 includes a first bottom surface 330 facing the pixel defining layer 200 and a first top surface 320 away from the pixel defining layer 200, and an orthographic projection of the first bottom surface 330 on the base plate 100 is located within an orthographic projection of the first top surface 320 on the base plate 100. In these embodiments, the size of the first bottom surface 330 is less than or equal to the size of the first top surface 320, and the first electrode 400 is very easily to be disconnected at the location of the first mask portion 300. In some embodiments, the pixel defining portion 210 includes a second top surface away from the base plate 100, and the first top surface 320 of the first mask portion 300 and the second top surface of the pixel defining portion 210 form a segment difference.

In one embodiment, as shown in FIG. 7, the cross-sectional area of the first mask portion 300 decreases gradually in a direction towards the base plate; or as shown in FIG. 8, the first mask portion 300 includes a first sub-layer and a second sub-layer located at a side of the first sub-layer away from the base plate, and an orthographic projection of the first sub-layer on the base plate is located within an orthographic projection of the second sub-layer on the base plate. Therefore, a concavity can be formed under the first top surface 320, and the first electrode 400 is very easily to be disconnected at the edge of the first mask portion 300 towards the second opening.

In one embodiment, as shown in FIG. 1, the orthographic projection of the second opening 410 on the base plate 100 is located within the orthographic projection of the first opening 310 on the base plate 100, and the size of the second opening 410 is less than or equal to the size of the first opening 310, and the first electrode 400 can be patterned through the first opening 310 to form the second opening 410.

In some embodiments, as shown in FIG. 2, the display panel further includes a second mask portion 700 arranged at a side of the base plate 100 away from the pixel defining layer 200, and an orthographic projection of the first electrode 400 on the base plate 100 at least partially overlaps an orthographic projection of the second mask portion 700 on the base plate 100. In these embodiments, the first electrode 400 can be patterned through the cooperation of the first mask portion 300 and the second mask portion 700, the first opening 310 can be formed in the first electrode 400 through the first mask portion 300, and the components within the base plate 100 can be protected by the second mask portion 700.

In one embodiment, the base plate 100 includes at least one drive circuit, and the orthographic projection of the second mask portion 700 on the base plate 100 at least partially overlaps the drive circuit. Therefore, the second mask portion 700 can reduce damage to the drive circuit by laser.

The embodiments of the second aspect of the present application further provide a display apparatus including the display panel of any one of the above embodiments of the first aspect. Specific details regarding the display panel can be found in the relevant description in the above embodiments and will not be repeated herein. Since the display apparatus of the embodiments of the present application includes the display panel of the above embodiments, the display apparatus of the embodiments of the present application has the beneficial effects of the display panel of any one of the above embodiments of the first aspect, which will not be repeated herein. Specifically, the display apparatus may be an apparatus with display function such as a cellular phone, a computer, a tablet computer, a television, an electronic paper, which is not limited herein.

The embodiments of the third aspect of the present application further provide a method for manufacturing a display panel, which may be the display panel of any one of the above embodiments of the first aspect.

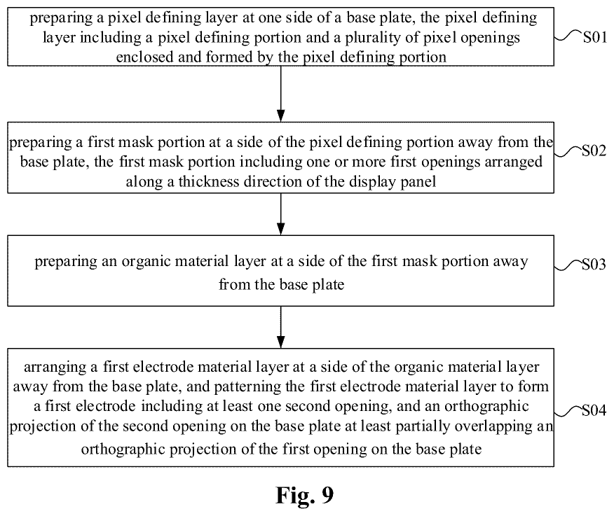

As shown in FIGS. 1 to 9, the method for manufacturing a display panel includes:
step S01: preparing a pixel defining layer 200 at one side of a base plate 100, the pixel defining layer 200 including a pixel defining portion 210 and a plurality of pixel openings 220 enclosed and formed by the pixel defining portion 210;
step S02: preparing a first mask portion 300 at a side of the pixel defining portion 210 away from the base plate 100, the first mask portion 300 including one or more first openings 310 arranged along a thickness direction Z of the display panel;
step S03: preparing an organic material layer 500 at a side of the first mask portion 300 away from the base plate 100; and
step S04: arranging a first electrode material layer at a side of the organic material layer 500 away from the base plate 100, and patterning the first electrode material layer to form a first electrode 400 including at least one second opening 410, and an orthographic projection of the second opening 410 on the base plate 100 at least partially overlapping an orthographic projection of the first opening 310 on the base plate 100.

In these embodiments, the pixel defining layer 200 can be first prepared by step S01. The pixel defining layer 200 includes the pixel defining portion 210 and the pixel openings 200, and the pixel openings 220 are configured to arrange light-emitting units to achieve light emitting and display of the display panel. The first mask portion 300 is then prepared on the pixel defining layer 200 by step S02, and the first mask portion 300 includes the first opening 310, and a height difference can be formed in the first mask portion 300 at the edge towards the first opening 310. Then the organic material layer 500 is formed on the first mask portion 300, followed by the formation of the first electrode material layer at the side of the organic material layer 500 away from the base plate 100. In patterning the first electrode material layer using the first mask portion 300, with the first opening 310, the second opening 410 can be formed in the first electrode 400, which can reduce the distribution area of the first electrode 400 and increase the light transmittance of the display panel. Moreover, since the first mask portion 300 is located at the side of the pixel defining portion 210 away from the base plate 100, the edge of the first mask portion 300 towards the first opening 310 can form a thickness difference, and thus the connection of the first electrode 400 at the first opening 310 of the first mask portion 300 is weak. When the first electrode 400 is laser patterned using the first mask portion 300 as a mask, the first electrode 400 is easily to be disconnected at the edge of the first opening 310, which can reduce the problem that the edge of the first electrode 400 towards the second opening 410 is likely to upwarp, thereby avoiding the uparping first electrode 400 from affecting the yield of the subsequent encapsulation layer, to increase the encapsulation reliability of the display panel.

In one embodiment, step S03 further includes: patterning the organic material layer 500 to form at least one through hole 510, and a portion of the first mask portion 300 is exposed by the through hole 510. Accordingly, step S04 further includes: interconnecting at least a portion of the first electrode material layer with the first mask portion 300 via the through hole 510. Therefore, the first electrode 400 subsequently prepared is interconnected with the first mask portion 300 via the through hole 510, which can reduce the impedance of the first electrode 400.

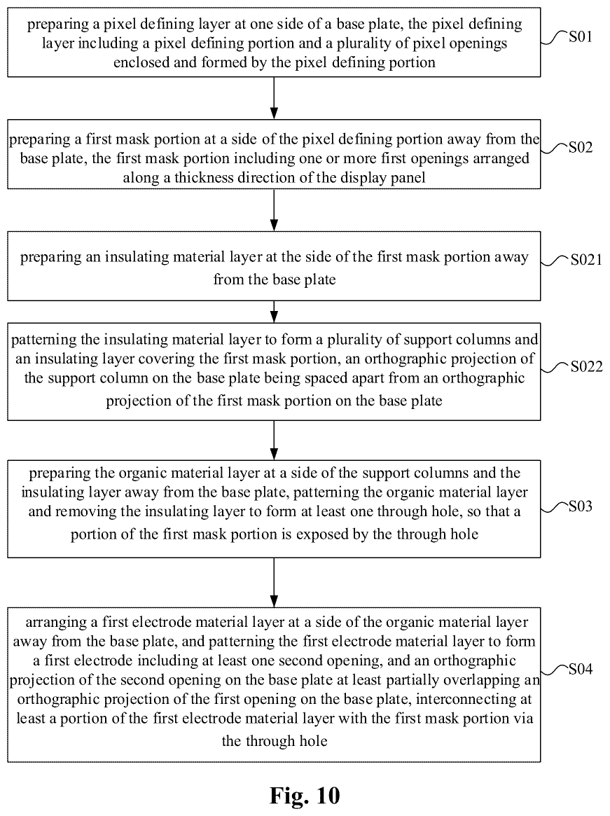

In some embodiments, as shown in FIG. 10, the method further includes, before step S03:
step S021: preparing an insulating material layer at the side of the first mask portion 300 away from the base plate 100; and
step S022: patterning the insulating material layer to form a plurality of support columns and an insulating layer 800 covering the first mask portion 300, an orthographic projection of the support column on the base plate 100 being spaced apart from an orthographic projection of the first mask portion 300 on the base plate 100.

Accordingly, step S03 includes: preparing the organic material layer 500 at a side of the support columns and the insulating layer 800 away from the base plate 100.

In these embodiments, before the organic material layer 500 are prepared, the support columns and the insulating layer 800 are formed on the first mask portion 300, and the insulating layer 800 covers the first mask portion 300. When the organic material layer 500 is prepared in the subsequent step S03, the insulating layer 800 is located between the organic material layer 500 and the first mask portion 300, which can reduce short circuit connection between the first mask portion 300 and the organic material layer 500.

In one embodiment, step S03 further includes: patterning the organic material layer 500 and removing the insulating layer 800 to form at least one through hole 510, and a portion of the first mask portion 300 is exposed by the through hole 510. Step S04 further includes: interconnecting at least a portion of the first electrode material layer with the first mask portion 300 via the through hole 510. Therefore, the first electrode 400 and the first mask portion 300 are electrically connected, which can reduce the impedance of the first electrode 400.

In one embodiment, a second mask portion 700 is arranged at a side of the base plate 100 away from the pixel defining layer 200. In step S04, a laser may be emitted from a side of the first electrode 400 towards the base plate 100 towards the first electrode 400, and the laser hits the first electrode material layer through the first opening 310, thereby causing a portion of the material of the first electrode material layer to peel off to form the second opening 410.

It should be noted that the various embodiments in the specification are described in a progressive manner, the same or similar portions of the embodiments may be cross-referenced, and each of the embodiments focuses on the differences from other embodiments. For the method embodiments and the display apparatus embodiments, the relevant portions can be found in the description of the display panel embodiments. The present application is not limited to the particular steps and structures described above and illustrated in the drawings.

What is claimed is:

1. A display panel, comprising:
a base plate;
a pixel defining layer arranged at one side of the base plate, the pixel defining layer comprising a pixel defining portion and a plurality of pixel openings enclosed and formed by the pixel defining portion;
a first mask portion located a side of the pixel defining portion away from the base plate, the first mask portion comprising one or more first openings arranged through the first mask portion along a thickness direction of the display panel; and
a first electrode located at a side of the pixel defining layer away from the base plate and a side of the first mask portion away from the base plate, the first electrode comprising at least one second opening arranged through the first electrode along the thickness direction, and an orthographic projection of the second opening on the base plate at least partially overlapping an orthographic projection of the first opening on the base plate.

2. The display panel according to claim 1, further comprising an organic material layer located at the side of the first mask portion away from the base plate, the organic material layer comprising one or more through holes arranged through the organic material layer along the thickness direction, and the first electrode being electrically connected with the first mask portion via the through holes.

3. The display panel according to claim 2, wherein an orthographic projection of the through hole on the base plate is located within an orthographic projection of the pixel defining portion on the base plate; or
the orthographic projection of the through hole on the base plate is located within an orthographic projection of the first mask portion on the base plate; or
the orthographic projection of the through hole on the base plate is spaced apart from the orthographic projection of the first opening on the base plate.

4. The display panel according to claim 2, wherein a plurality of the through holes are distributed at intervals; or
at least one through hole is arranged between two pixel openings adjacent along a first direction, the first opening is located at one side of the through hole in a second direction, and the first direction intersects the second direction.

5. The display panel according to claim 2, wherein an insulating layer is arranged between the first mask portion and the organic material layer.

6. The display panel according to claim 1, wherein the first opening extends along a first direction, a plurality of the first openings are distributed at intervals along a second direction, and the first direction intersects the second direction.

7. The display panel according to claim 6, wherein the display panel comprises a first display area and a second display area arranged around at least a portion of the first display area, a light transmittance of the first display area is greater than a light transmittance of the second display area, and the first opening extends within the first display area along the first direction to a boundary between the first display area and the second display area; or
the display panel comprises a display area and a non-display area surrounding at least a portion of the display area, and the first opening extends in the display area along the first direction to a boundary between the display area and the non-display area.

8. The display panel according to claim 6, wherein the first electrode comprises a first sub-portion and a second sub-portion connected with each other, the first sub-portion extends along the first direction, the first electrode comprises a plurality of the first sub-portions, the plurality of first sub-portions are arranged at intervals along the second direction, and the second sub-portion is located at at least one side of the first sub-portion in the first direction and configured to connect at least two adjacent ones of the first sub-portions.

9. The display panel according to claim 1, wherein
the first mask portion has a thickness greater than or equal to 1000 angstroms.

10. The display panel according to claim 1, wherein a material of the first mask portion comprises an electrically conductive material; or
the material of the first mask portion comprises one or more of silver, indium tin oxide, molybdenum, titanium, or aluminum.

11. The display panel according to claim 1, wherein the first mask portion comprises a first bottom surface facing the pixel defining layer and a first top surface away from the pixel defining layer, and an orthographic projection of the first bottom surface on the base plate is located within an orthographic projection of the first top surface on the base plate.

12. The display panel according to claim 1, wherein a cross-sectional area of the first mask portion decreases gradually in a direction towards the base plate; or the first mask portion comprises a first sub-layer and a second sub-layer located at a side of the first sub-layer away from the base plate, and an orthographic projection of the first sub-layer on the base plate is located within an orthographic projection of the second sub-layer on the base plate.

13. The display panel according to claim 11, wherein the orthographic projection of the second opening on the base plate is located within the orthographic projection of the first opening on the base plate; or
the pixel defining portion comprises a second top surface away from the base plate, and the first top surface and the second top surface form a segment difference.

14. The display panel according to claim 1, further comprising a second mask portion arranged at a side of the base plate away from the pixel defining layer, and an orthographic projection of the first electrode on the base plate at least partially overlapping an orthographic projection of the second mask portion on the base plate.

15. The display panel according to claim 14, wherein the base plate comprises at least one drive circuit, and the orthographic projection of the second mask portion on the base plate at least partially overlaps the drive circuit.

16. A display apparatus comprising the display panel according to claim 1.

17. A method of manufacturing a display panel, comprising:
preparing a pixel defining layer at one side of a base plate, the pixel defining layer comprising a pixel defining portion and a plurality of pixel openings enclosed and formed by the pixel defining portion;
preparing a first mask portion at a side of the pixel defining portion away from the base plate, the first mask portion comprising one or more first openings arranged along a thickness direction of the display panel;
preparing an organic material layer at a side of the first mask portion away from the base plate; and
arranging a first electrode material layer at a side of the organic material layer away from the base plate, and patterning the first electrode material layer to form a first electrode comprising at least one second opening, and an orthographic projection of the second opening on the base plate at least partially overlapping an orthographic projection of the first opening on the base plate.

18. The method according to claim 17, wherein the preparing the organic material layer at the side of the first mask portion away from the base plate further comprises: patterning the organic material layer to form at least one through hole, and a portion of the first mask portion is exposed by the through hole; and
the preparing the first electrode material layer at the side of the organic material layer away from the base plate further comprises: interconnecting at least a portion of the first electrode material layer with the first mask portion via the through hole.

19. The method according to claim 17, further comprises, before the preparing the organic material layer at the side of the first mask portion away from the base plate:
preparing an insulating material layer at the side of the first mask portion away from the base plate; and
patterning the insulating material layer to form a plurality of support columns and an insulating layer covering the first mask portion, an orthographic projection of the support column on the base plate being spaced apart from an orthographic projection of the first mask portion on the base plate;
the preparing the organic material layer at the side of the first mask portion away from the base plate further comprises: preparing the organic material layer at a side of the support columns and the insulating layer away from the base plate.

20. The method according to claim 19, wherein the preparing the organic material layer at the side of the first mask portion away from the base plate further comprises: patterning the organic material layer and removing the insulating layer to form at least one through hole, and a portion of the first mask portion is exposed by the through hole; and
the preparing the first electrode material layer at the side of the organic material layer away from the base plate further comprises: interconnecting at least a portion of the first electrode material layer with the first mask portion via the through hole.
